(19) United States
(12) Patent Application Publication
(10) Pub. No.: US 2006/0031031 A1
(43) Pub. Date: Feb. 9, 2006

(54) Method and apparatus for processing eye diagram data

(76) Inventor: Robert C. Cohn, Beaverton, OR (US)

Correspondence Address: Thomas F. Lenihan;Tektronix, Inc., M/S 50-LAW, P.O. Box 500, Beaverton, OR, 97077-0001, US

(21) Appl. No.: 10/912,786

(22) Filed: Aug. 6, 2004

(51) Int. Cl. G01R 13/00; G06F 19/00

(52) U.S. Cl. 702/66

(57) ABSTRACT

Method for processing eye diagram data from a system under test includes mapping channels of a logic analyzer for eye diagram data signal acquisition to DSO inputs, acquiring signals from the channels, determining if there are additional channels for signal acquisition and in response to the completion of acquisition signals, automatically mapping the additional channels to the DSO inputs and acquiring data signals from the additional channels. The steps are repeated until all selected channels are analyzed. An apparatus includes means for selecting a first plurality of channels for eye diagram signal acquisition and mapping the first plurality of channels to DSO inputs, means for acquiring a first plurality of signals from the first plurality of channels, means for sending a completion of acquisition signal and means for automatically mapping a second plurality of channels for eye diagram signal acquisition to the DSO inputs in response to the completion of acquisition signal. The DSO then sends the eye diagram data to the Logic Analyzer for display.

### FIELD OF THE INVENTION

The invention relates generally to signal acquisition systems and, more particularly, to a method and apparatus for processing eye diagram data in a logic analyzer.

### BACKGROUND OF THE INVENTION

Signal acquisition devices such as logic analyzers (LAs) are instruments used for verifying and debugging digital circuits. Specifically, a logic analyzer verifies that a digital circuit is working and provides information for troubleshooting such a circuit. The logic analyzer is capable of capturing and displaying many signals of the digital circuit at one time and analyzing their timing relationships. Since timing relationships in digital circuits are paramount to their correct functioning, verifying these relationships (preferably by visual analysis) with an LA is highly useful. For example, FIG. 1 depicts voltage-time eye (VTE) data 100 for a particular system under test (SUT). Multiple channels 104 are graphed against a clock transition 102 on the same display. Such a diagram is built up over many thousands of waveform acquisitions 106₁, 106₂ (i.e. from an external digital storage oscilloscope (DSO)) in which each waveform can be thought of as overlaying waveforms already captured. Using such a VTE diagram, a user can verify whether channels meet setup and hold requirements. That is, no channel transitions should be occurring within a setup time 112 prior to the clock transition 102 up to a hold time 114 following the clock transition 102. In the example in FIG. 1, one channel 110 does not meet the setup and hold specifications as its data cuts through the setup time 112 prior to the clock transition 102.

Creating a VTE diagram is a standard feature of many DSOs from companies such as Tektronix, Inc. of Beaverton, Oreg. and is used extensively throughout the electronics industry to characterize signal stability. Unfortunately, this feature does not exist in LA's; therefore, it is necessary to manually readjust DSO probes and somehow feed the captured VTE data of up to hundreds of signal channels to an LA to arrive at the desired analysis. For example, in a signal bus consisting of 32 signals available for VTE analysis, a user would have to connect probes from the DSO to each signal of the bus and have the DSO perform data acquisitions and produce the VTE data. Since most DSO's are limited to four input channels, performing analysis on a 32 signal bus would require the user to move each of the three probes being used for signal capture at least ten times (assuming there are four DSO channels and that one channel is reserved for clocking). When each set of VTE data for a group of three channels is captured, the user would have to save the data and export it to another viewing tool (for example, Microsoft Excel®). By such a process, the user could eventually capture VTE data for all 32 channels and export it to the external tool for aggregation and viewing but only after laborious and repetitive manual steps that can easily produce errors.

### SUMMARY OF INVENTION

Various deficiencies in the prior art are addressed by the present invention of a method and apparatus for processing eye diagram data from a system under test. The method includes the steps of (a) mapping a first plurality of channels for eye diagram data signal acquisition to a plurality of DSO inputs, (b) acquiring a first plurality of signals from the first plurality of channels, (c) determining if there are additional channels for signal acquisition and (d) automatically mapping a second plurality of channels for eye diagram signal acquisition to the plurality of DSO inputs and acquiring at least a second plurality of data signals from the second plurality of channels. These steps are repeatable until all selected channels in a system under test are analyzed. The method further includes the step of analyzing the first plurality of signals and providing statistical data regarding the eye diagram data. The statistical data provides a determination of instances where the first and second pluralities of acquired signals did not conform to predefined user parameters. Such results are displayable on a user interface after each plurality of channels is analyzed. The mapping step includes dedicating at least one of the DSO inputs to data other than from the first plurality of channels and in one embodiment the dedication is to a clock signal against which the other signals are analyzed for VTE data.

An apparatus in accordance with the subject invention includes means for selecting a first plurality of channels for eye diagram signal acquisition and mapping the first plurality of channels to a plurality of DSO inputs, means for acquiring a first plurality of signals from the first plurality of channels, means for sending a completion of acquisition signal with respect to the first plurality of channels and means for automatically mapping a second plurality of channels for eye diagram signal acquisition to the plurality of DSO inputs. The means for selecting a first plurality of channels for eye diagram signal acquisition and mapping the first plurality of channels to a plurality of DSO inputs is an analog multiplexer in a logic analyzer acting in response to a set of user parameters. The means for automatically mapping a second plurality of channels for eye diagram signal acquisition to the plurality of DSO inputs is the analog multiplexer acting in response to the completion of acquisition signal. The apparatus also includes means for displaying analysis results of the signal acquisitions on the logic analyzer and in one embodiment is a user interface depicting an aggregate graphing of analysis results for all analyzed channels.

### BRIEF DESCRIPTION OF THE DRAWINGS

The teachings of the present invention can be readily understood by considering the following detailed description in conjunction with the accompanying drawings, in which:

FIG. 1 depicts a VTE timing diagram existing in the prior art;

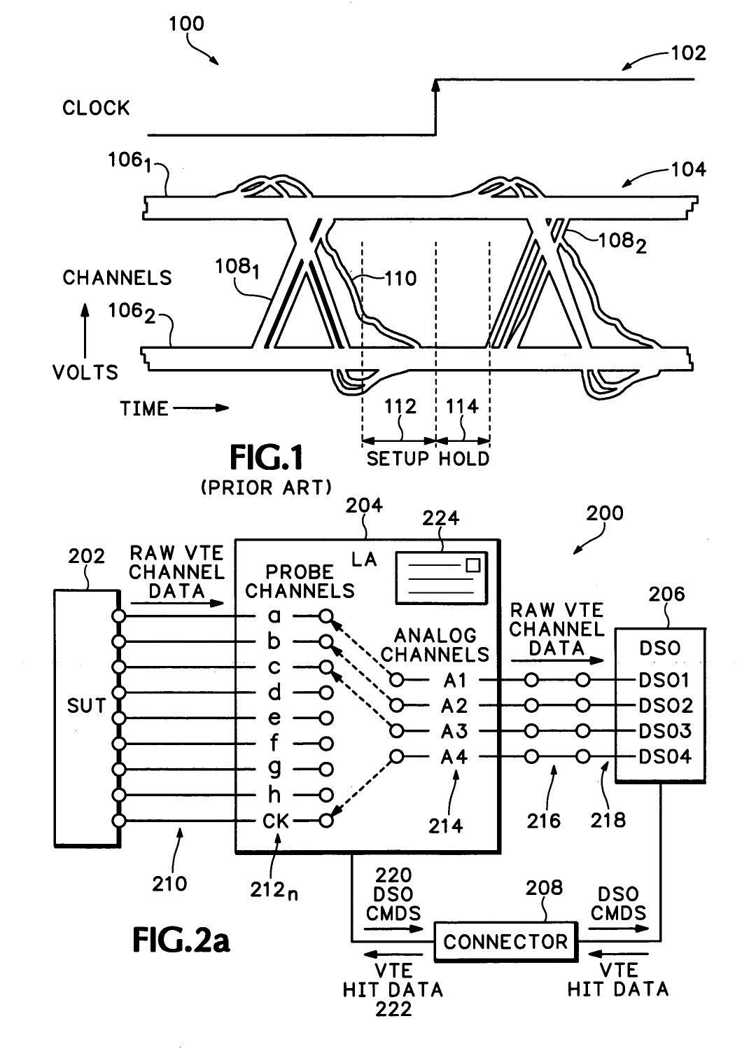

FIGS. 2a-2c depict a time lapse sequence view of VTE analysis in an apparatus in accordance with the subject invention;

FIG. 3 depicts a series of method steps for processing eye diagram data in accordance with the subject invention;

FIG. 4 depicts a user interface displaying results of eye diagram data processing in accordance with the subject invention; and

FIG. 5 depicts a modular view of an apparatus for processing eye diagram data in accordance with the subject invention.

To facilitate understanding, identical reference numerals have been used, where possible, to designate identical elements that are common to the figures.

### DETAILED DESCRIPTION OF THE INVENTION

The subject invention provides for improved circuitry and operational methods for processing eye diagram data captured from SUTs in an LA. Generally speaking, the invention performs automatic capturing of multiple channels of data, multiplexes the data and passes the data to a DSO for display. Accordingly, the basic problem of the physical channel limitations of most DSOs as well as the high degree of user interaction and manipulation of equipment is addressed. With the subject invention, multiple channels (above the number of input DSO channels) can be sampled by connecting a probe once, and the VTE data from all channels can be aggregated into the same data display where it can be further analyzed.

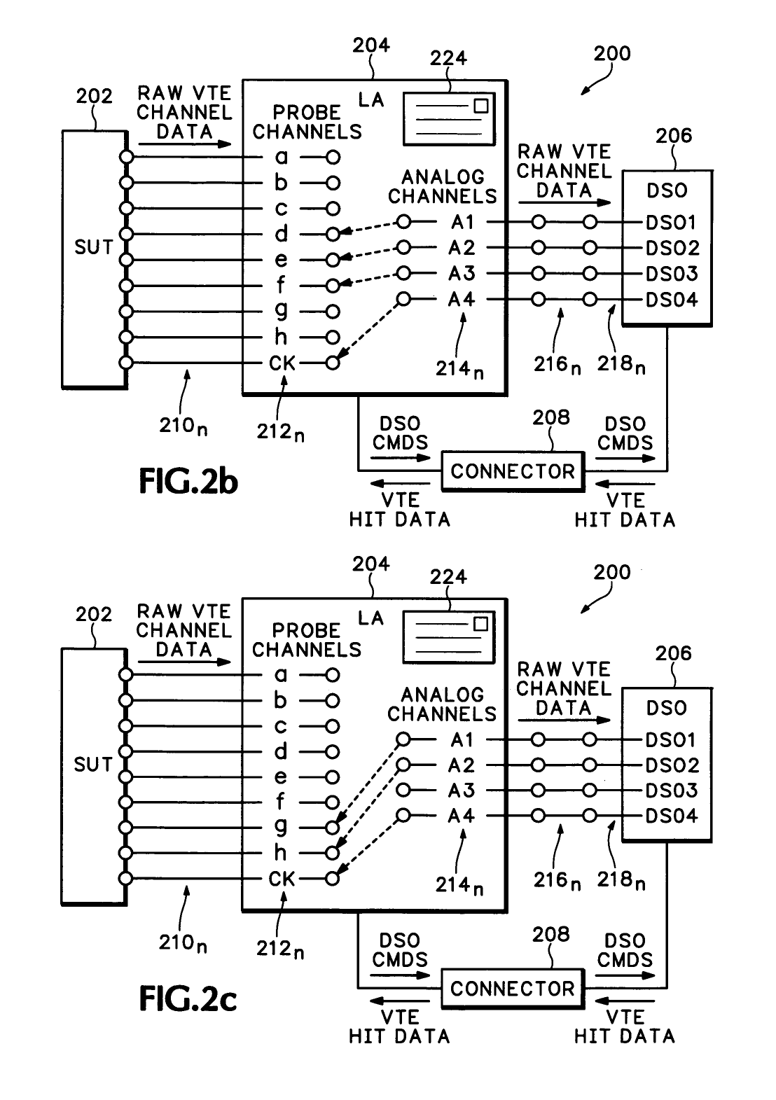

FIG. 2 depicts a time lapse view of a system 200 for VTE analysis in accordance with the subject invention. Specifically, FIG. 2a depicts a first configuration for VTE data capture. FIGS. 2b and 2c depict second and third configurations respectively for VTE data capture in the system 200. The system 200 includes a system under test 202 which is any typical circuit or subsystem that provides signals indicative of its operational states via a plurality of SUT signals. A logic analyzer (LA) 204 receives the SUT signals via a plurality of probes 210, each of which are connected to a respective plurality of LA probe channels 212. The LA 204 includes a multiplexing feature that allows the user to capture analog data (using the same probes used to sample digital data) and route that analog data to a plurality of output analog channels 214. These LA analog output channels 214 are then externally connected via a plurality of connections 216 to a corresponding plurality of DSO channel inputs 218. The DSO's 206 sampling setup, which is automatically programmed by the LA 204 through a connection between the two instruments, controls how the data is sampled through the plurality of probes. The user then directs the LA 204 to query the DSO for the just-captured data, time correlate it to other data channels, and then display it in a LA data window. Thus, the user takes advantage of the higher and more accurate sampling capabilities of the external DSO to examine high-resolution analog data channels. Such an analog multiplexing feature is provided in the TLA7AXx family of logic analyzer acquisition modules, which are used in the TLA715 and TLA721 logic analyzer products by Tektronix, Inc. of Beaverton, Oreg. The analog multiplexer used with the present invention is described in U.S. published patent document 20030160625, entitled CAPTURING BOTH DIGITAL AND ANALOG FORMS OF A SIGNAL THROUGH THE SAME PROBING PATH (Kaufman, et al.), published 28 Aug. 2003, and is further described in pending U.S. patent application Ser. No. 10/365,202 claiming priority from the above-mention published U.S. provisional patent application and filed on 11 Feb. 2003. Both of these patent applications are herein incorporated by reference in their entirety. Control of the LA, and the invention in general, is provided via a user interface 224. The user interface 224 is displayed on an LA's embedded display or on an attached video monitor. Note that different LA's will require a supporting LA module be installed for proper user interface 224 operation.

Also shown in FIG. 2a is a connector 208 between the LA 204 and DSO 206. A command data path 220 (e.g., a bundle of connections linking trigger and signal outputs from the LA 204 to the DSO auxiliary and clock inputs 206) carries control information and VTE hit data path 222 moves VTE hit data back to the LA 204. In the context of the subject invention, VTE hit data for a specific voltage/time (V/T) location is the number of times a signal intersects that location. Over many acquisitions, the signal may or may not intersect this particular V/T location. The count of times intersected is the number of “hits” at that location, and it is statistical in nature. In one embodiment, the connector contains a USB to GPIB adapter that allows commands to be sent to the DSO 206 and VTE hit data to be sent back to the LA 204.

For example, consider that the user wants to obtain the analog representations of eight channels: a, b, c, d, e, f, g, and h in the LA 204 and there are only four LA analog outputs 214 and only four DSO channel inputs 218 available. Using the multiplexing feature, the user selects the channels to be analyzed and the invention maps a first plurality of channels (i.e., a, b and c) to LA analog outputs A1, A2 and A3 respectively while A4 is reserved for CK. Further, the subject invention maps analog outputs A1, A2, A3 and A4 to DSO channels DSO1, DSO2, DSO3 and DSO4 respectively. Thus, channel a is sampled by the DSO through its DSO1 channel, channel b through DSO2, and the like. After the DSO has completed its data acquisitions on the first plurality of channels, the LA 204 (through the connector 208) queries the DSO 206 for data from the first plurality of channels and displays it in a data view.

After the first plurality of channels have been sampled, the invention remaps the LA analog outputs 214 to gather data for a second plurality of channels. For example, this mapping can be: channel d to A1, e to A2, f to A3 and CK to A4. One skilled in the art appreciates that the specific mapping does not affect the results of the analysis nor narrow the scope of the invention as any combination of mappings is possible. No change needs to be made to the analog output cable connections 214 to DSO channel 218 mappings. The invention then directs the DSO 206 to sample the second plurality of channels. Once again, the data can be queried for and displayed on the LA 204. However, data from the second plurality of channels is aggregated to the existing data from the first plurality of channels to provide a display of all selected channels. Lastly, a third (and/or additional) plurality of channels (i.e., g and h) are analyzed in subsequent passes, with g connecting to A1 and h connecting to A2, and the CK connecting to A4 (connection A3 is not used) as shown in FIG. 2c. to complete the analysis of all user-selected channels.

FIG. 2a shows the first plurality of connections between the SUT, the LA 204 and the DSO 206. Data comes in through the LA probe channels 212, is redirected (multiplexed) onto the Analog channel outputs 214 and finally forwarded to the DSO channel inputs 218. The subject invention reroutes the analog channels 214 to different probe channels 212 automatically to cycle through all of the probe channels to be analyzed. Again, although not shown, the subject invention can reroute the analog channels connections to any of the DSO channels without affecting the result or scope of the invention. For example, the invention routes analog channel A1 to DSO3. The subject invention also makes the decision for this channel mapping as well, informing the user how the probes must be connected between the LA 204 and DSO 206. Therefore, the user does not have to decide how to do the channel mappings described above. The user needs only select the channels to be analyzed, the clock and/or qualifier channel to be used, connect both the LA probes and analog probes once, and allow the subject invention to cycle through all of the channels to be analyzed.

FIG. 2b depicts a second plurality of connections between the SUT, the LA 204 and the DSO 206. That is, probe channels d, e and f are now mapped to analog channels A1, A2 and A3 respectively (with A4 still being mapped to the trigger or Clock). This remapping occurs after a completion signal is sent by the DSO 206 indicating that all signal acquisition duties have been performed with respect to channels a, b and c. Similarly, FIG. 2c depicts a third plurality of connections between the SUT, the LA 204 and the DSO 206. That is, probe channels g and h are now mapped to analog channels A1 and A2 respectively (with A4 still being mapped to the trigger or Clock and A3 being unmapped as there are no other additional SUT channels requiring analysis). This remapping occurs after a completion signal is sent by the DSO 206 indicating that all signal acquisition duties have been performed with respect to channels d, e and f.

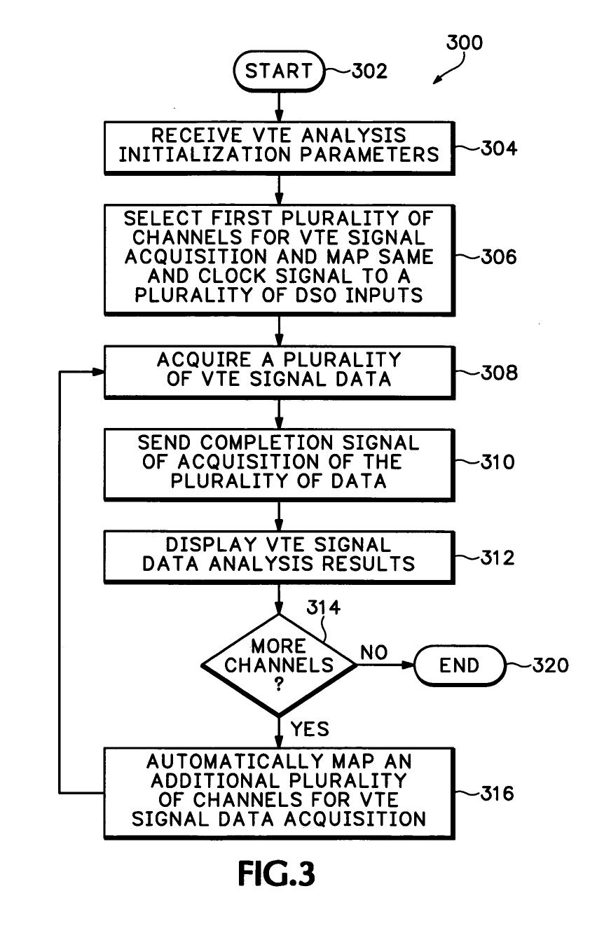

FIG. 3 depicts a series of method steps 300 for conducting automated processing of VTE data received from SUTs. Specifically, the method starts at step 302 and proceeds to step 304 where initialization parameters for VTE analysis are received. In one embodiment of the invention, a user provides such parameters via a user interface that is interacting in accordance with the method. In one embodiment, initialization parameters include one or more of a module from which to pick the analysis channels, the channels to be analyzed, a clock channel and an edge transition, a time range (relative to the clock edge) over which the DSO will perform its sampling, a vertical range (which indicates the vertical voltage extent over which analysis occurs for each channel), an approximate stop condition and an oscilloscope acquisition mode.

Such parameters afford the user with a broad range of control over the automated process. For example, the LA 204 represents a logical module to the user and it can be either a single physical LA acquisition module or a merged set of LA acquisition modules for selection purposes. Additionally and as indicated earlier there can be up to eight channels in a single LA (a, b, c, d, e, f, g, and h) subject to analysis. However, a single LA module can support up to 136 channels. Therefore, the subject invention can analyze up to that many channels for a single module (considering also that one of those channels must be used as a clock). If additional modules are logically merged, many hundreds more channels can be analyzed in a single analysis. Additionally, selecting a clock channel allows the user a degree of freedom in the automated mapping process and the edge transition is selectable from going high or going low. For the time range, one embodiment is in the range of approximately −10 ns to 10 n. Preset vertical ranges are selectable from the group consisting of TTL, CMOS and ECL, or the user may define his own range. For the presented example, assume the user has selected TTL. The stop condition is preferably expressed in minutes, and in one embodiment has a default value of 1 minute. The oscilloscope acquisition mode allows the user to take advantage of various features if supported in the connected scope.

The method then proceeds to step 306 where a first plurality of channels for VTE signal acquisition are selected and subsequently mapped to a plurality of oscilloscope inputs. In one embodiment where the oscilloscope is a 4 channel DSO and one channel is reserved for clock signaling, the first plurality of channels is three (a, b and c) and said first plurality of channels is mapped to the first three DSO inputs, and the clock is mapped to the fourth DSO input. After selection and mapping of the first plurality of channels, the method proceeds to step 308 where VTE signal data is acquired from the SUT. Specifically, commands are sent to the DSO so that data from the SUT enters the first plurality of LA channels and is passed (multiplexed) to the DSO inputs via analog channel outputs of the LA.

At step 310, acquisition of the VTE data of the first three (plurality) of channels is completed and a completion signal is sent by the DSO. This completion signal is recognized by other system components that, in turn, execute ancillary subroutines for managing and processing the acquired VTE data.

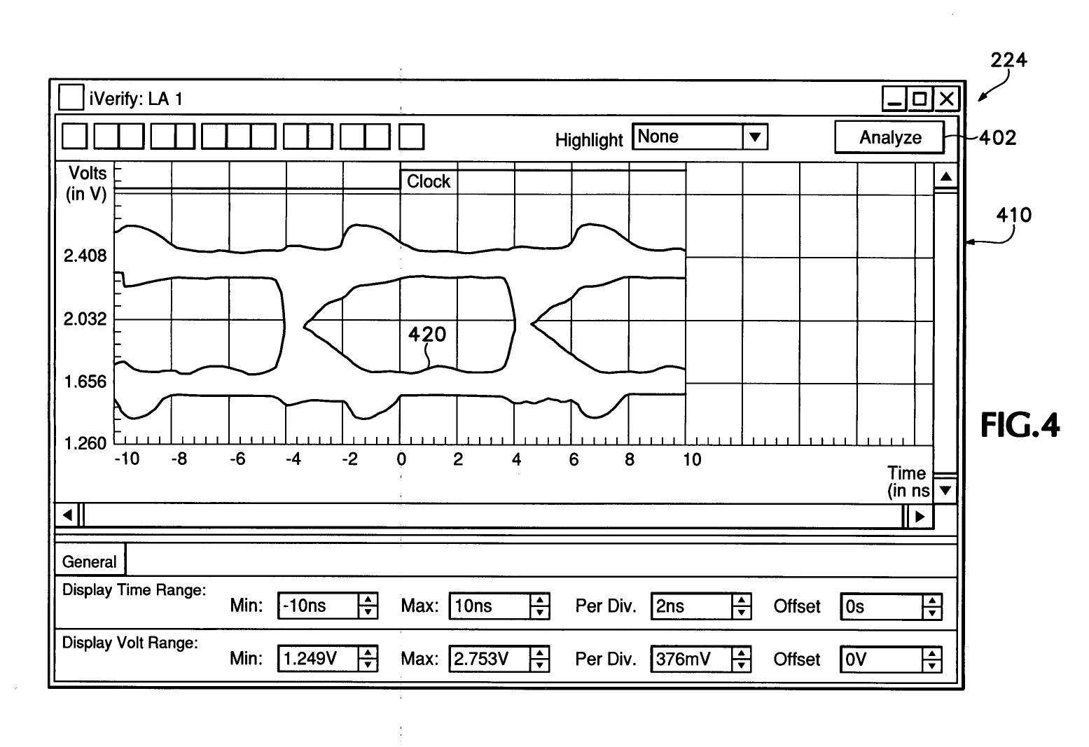

At step 312, the VTE data acquired from the first plurality of channels is displayed. That is, the LA 204 queries the DSO 206 for the VTE data acquisition results and then formats and displays such results. In one embodiment, the display is in the form of an aggregate graphical display of VTE “hit” data. That is, the result of performing the analysis of the subject invention is an aggregate VTE diagram of the data for all analyzed channels. During analysis, if the DSO detects that a channel's signal intercepts a voltage, time (VT) pair point, then it registers a “hit” on that point. Since the DSO captures thousands of waveforms per second, it can build up a very accurate statistical sampling of all data points in a VT grid. A VT hit of 100 for a particular channel means that the DSO recorded 100 occurrences of the channel waveform data having that particular VT value pair. In one embodiment depicted in the user interface 224 of FIG. 4, the data view itself comprises a 200×500 pixel image 410, in which the pixels have relatively greater intensity according to the number of “hits” obtained during analysis around particular points. Each pixel location represents a Voltage/Time sampling point from the DSO analysis. Therefore, the resulting data view is a statistical representation of the analysis channels as the DSO sweeps through the user-defined voltage and time range. As mentioned above, a user interface may vary the pixel intensity (or color) according to a value range. For example, in image 410, relatively darker shaded area 420 denotes the color red which can mean a very high number of hits, and blue (not shown) can mean very low number of hits. Note that a pixel that is colored with the background color of the data display indicates a VT point in which no hits occurred for any analysis channel.

At step 314, a decision step is invoked. Specifically, a query is made as to whether there are more channels to be analyzed according to the user-defined parameters. If there are no more channels to be analyzed, the method proceeds to an ending step 320. If there are more channels to be analyzed, the method proceeds to step 316. At step 316, the method, having completed acquisition, analysis and display of the first plurality of channels and related data, automatically selects and maps a second plurality of channels for VTE signal acquisition without further instruction, input or activity by the user. That is, the method continues to run uninterrupted until all channels are analyzed by virtue of the initialization parameters entered at step 304. Specifically, steps 308, 310 and 312 are repeated for at least the second plurality of channels for VTE signal acquisition. Further, these steps are repeated for any and all additional pluralities of channels until all channels are analyzed and their “hit” results displayed at the user interface.

Additional considerations for the subject invention allow for other types of channel usage with certain provisions. If the user also selects a qualifier channel, then one of the four DSO channels must be committed to that qualifier. Accordingly, this leaves only two DSO channels to be used to cycle through all of the analysis channels. Thus, for eight analysis channels, there would be four (eight analysis channels divided by two DSO channels) instead of three analyses passes. A user might use a qualifier channel to “advise” the DSO that it is OK to sample data based on the specified clock transition. Not all rising clock transitions, for example, may be legitimate transitions upon which to sample data. The user may specify that the qualifier must have a high or low state to “qualify” the clock transition.

If the user is selecting analysis channels from a LA merged module set (in which both modules support the LA multiplexing feature), then analysis channels can be selected from any module in the set, and the clock and qualifier channels can also be selected from any module in that set. It is not possible to select analysis channels and clock and qualifier channels from different unmerged modules. For example, if there are two modules, M1 and M2, that are not logically merged, then the user must get all analysis, clock and qualifier channels from either M1 or M2. However, if M1 and M2 are merged to form the logical module M3, then the user may select some analysis channels from the physical module M1, some from M2, and the clock and qualifier channels from either M1 or M2.

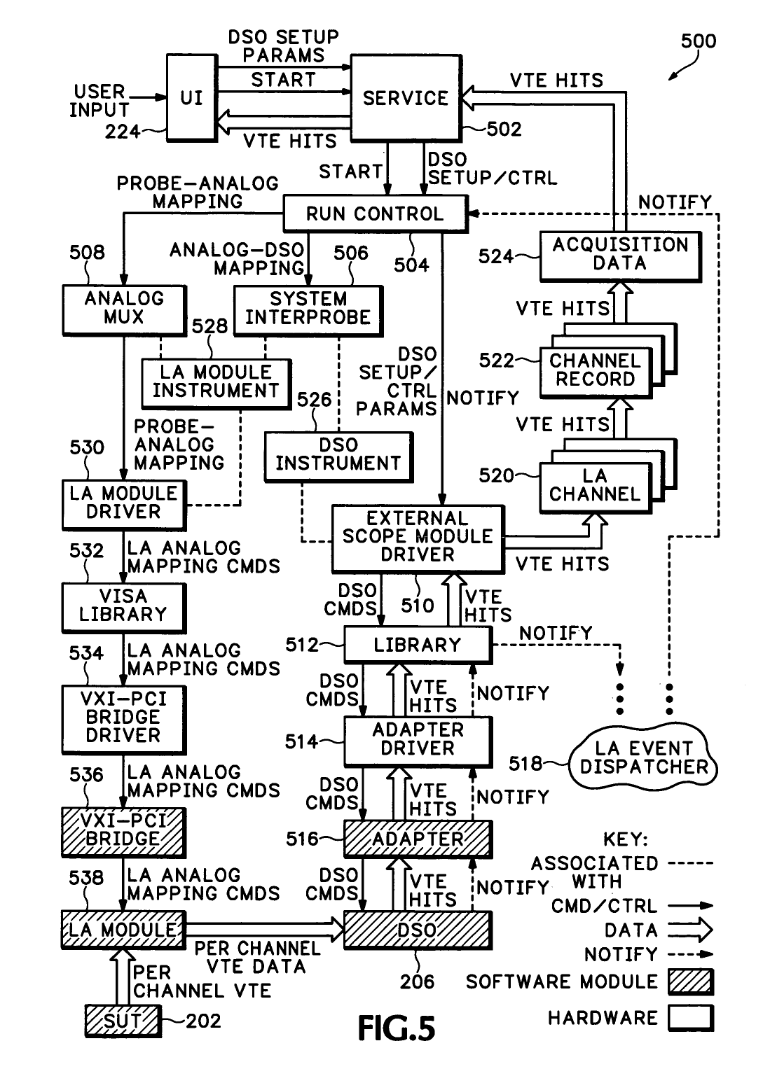

The method of the subject invention is implemented by passing commands and data through a series of software layers between a user and module acquisition hardware. FIG. 5 depicts a block diagram 500 of the time-lapse depicted system 200 of FIGS. 2a-c for practicing the method 300 of the subject invention. Various types of information pass from one element to another in the system 500. The key in FIG. 5 identifies these various types of information as different line segments drawn between system elements and is described in greater detail below. Specifically, a user enters initialization parameters (such as that described in step 304 of method 300 above) through the user interface display. Note that an “instrument” is a logical construction that may consist of one or more modules with respect to FIG. 5. For purposes of this example, we will assume that the instrument consists of just one module. Once the user has entered the parameters into the interface, then he presses the Analyze button (402 of FIG. 4) to begin the analysis.

An overview of the data and control paths from the user input to the final display of (iVerify) VTE results is depicted in FIG. 5. The user interface 224 uses the facilities of a Service Module 502 to display legal combinations of channels, clocking and DSO configuration parameters from which the user may select. For example, the Service Module 502 limits channel selection to only those LA modules that support invention functionality.

Once the user has entered parameter selections, they are sent to a Run Control Module 504. The Run Control Module 504 ensures that the proper setup is performed by three other modules: a System Interprobe Module 506, which manages analog channel to DSO channel mapping via a DSO instrument module 526 and an LA instrument module 528; an Analog Multiplexer Module 508, which is responsible for LA probe to analog channel mapping; and an External Scope Module driver 510, which sends setup and control commands to the DSO 206 to configure and initiate waveform acquisitions. These commands propagate down through a support library 512, an adapter driver 514, through adapter hardware 516 and finally to the DSO 206. In one embodiment of the invention, the library is a GPIB library and the adapter driver and hardware are USB-to-GPIB based devices. In one embodiment, the USB-to-GPIB adapter is part of the connector 208 of FIG. 2.

When the DSO 206 completes acquisitions for one set of channels, it sends a completion event that propagates up through the adapter 516, the adapter driver 514, and the library 512. Subsequently, an event notification is sent to a LA event dispatcher 518. The LA event dispatcher 518 executes code in the Run Control Module 504, which sends the necessary commands down through the software layers to the DSO 206 asking for just-acquired VTE hit data. The DSO 206 passes the VTE hit data back up through the software layers to the External scope module driver 510.

Subsequently, the VTE hit data is passed through a series of structures. A LA channel structure 520 and a Channel Record structure 522 handle per channel data (as indicated by the fact that there are multiple instances of these objects). Although these two structures seemingly perform the same function, they are actually two sides of an interface defined by the LA's TPI.NET architecture. The structure of the TPI.NET architecture relies on Microsoft Windows .NET technology and is well-known to those skilled in the art.

Once the per channel data is collected, it is managed by an Acquisition Data object 524, which is used by the Service Module 502 to honor data requests by the user interface 224. Upon reaching the user interface 224, the data is graphed in aggregate fashion for all channels.

Multiplexing of the various channels to enable data from the SUT 202 to be sampled and routed to the correct DSO channels is accomplished by an LA module driver 530 and its supporting components. That is, all LA analog mapping commands generated by the LA module driver 530 and going to LA module hardware 538 must go through a VISA library module 532, a VXI-to-PCI bridge driver 534 and a VXI-to-PCI bridge 536. Such driver modules 534 (implemented as software) can be found on any operating system (Windows and Linux are two examples), although each operating system has its own requirements on how a driver should be designed. A VXI-to-PCI bridge is a piece of electronic hardware that must provide data transfer and event notification between a PCI bus and a VXI bus, which are two well-known computing bus standards.

Accordingly, the subject method and apparatus automatically detect the VTE hit data for signals of an SUT enabling the user to ultimately reduce skewing effects of those signals with respect to a clock transition. While the foregoing is directed to the preferred embodiment of the present invention, other and further embodiments of the invention may be devised without departing from the basic scope thereof, and the scope thereof is determined by the claims that follow.

What is claimed is:

1. A method for processing eye diagram data comprising:
(a) mapping a first plurality of input channels of a logic analyzer to a set of analog output channels of said logic analyzer, said input channels being coupled to receive signals of a circuit under test;
(b) applying signals developed at said set of output channels to respective input terminals of a digital oscilloscope for eye diagram data signal acquisition;
(c) acquiring a first plurality of data signals from said respective input channels of said digital oscilloscope;
(d) determining if there are additional channels for signal acquisition;
(e) mapping at least a second plurality of channels to said set of output the plurality of DSO inputs and acquiring at least a second plurality of data signals from said second plurality of channels; and
(f) communicating said eye diagram data to said logic analyzer for display on said logic analyzer.

2. The method of claim 1 wherein the step of mapping is performed in response to selections entered via a user interface adapted to receive a set of parameters for multiplexing all selected channels.

3. The method of claim 2 wherein the set of parameters comprises a module from which to pick the analysis channels, the channels to be analyzed, a clock channel and an edge transition, a time range over which a DSO will perform data acquisition, a vertical range (voltage) for each channel, an approximate stop condition and an oscilloscope acquisition mode.

4. The method of claim 2 wherein steps (d)-(e) are repeated until all selected channels are analyzed.

5. The method of claim 1 further comprising the step of analyzing said first plurality of data signals and providing statistical data regarding the eye diagram data.

6. The method of claim 5 wherein the statistical data provides a determination of instances where the first and second pluralities of acquired signals did not conform to predefined user parameters.

7. The method of claim 1 wherein the step of mapping includes dedicating at least one of the DSO inputs to a clock signal from said circuit under test.

8. The method of claim 1 further comprising the step of sending a completion of acquisition signal prior to step (d).

9. The method of claim 8 wherein the completion of acquisition signal is generated by said digital oscilloscope.

10. Apparatus for processing eye diagram data comprising:
a logic analyzer having means for mapping a first plurality of input channels of said logic analyzer to a set of analog output channels of said logic analyzer, said input channels being coupled to receive signals of a circuit under test;
a digital oscilloscope for receiving signals developed at said set of output channels, said output channels of said logic analyzer being coupled to respective input terminals of said digital oscilloscope for eye diagram data signal acquisition;
said digital oscilloscope acquiring a first plurality of data signals from said respective input channels of said digital oscilloscope;
said logic analyzer determining if there are additional channels for signal acquisition;
in response to a determination of additional channels for signal acquisition, said logic analyzer mapping at least a second plurality of channels to said set of output channels for coupling to said plurality of DSO inputs and acquiring at least a second plurality of data signals from said second plurality of channels; and
said digital oscilloscope communicating said eye diagram data to said logic analyzer for display on said logic analyzer.

11. The apparatus of claim 10 further comprising means for selecting desired channels for eye diagram data signal acquisition.

12. The apparatus of claim 11 wherein the means for selecting the desired channels for eye diagram signal acquisition is a user interface adapted to receive a set of parameters for multiplexing the plurality of selected channels.

13. The apparatus of claim 12 wherein the set of parameters comprises one or more of a module from which to pick the analysis channels, the channels to be analyzed, a clock channel and an edge transition, a time range over which a DSO will perform data acquisition, a vertical range (voltage) for each channel, an approximate stop condition and an oscilloscope acquisition mode.

14. The apparatus of claim 13 wherein the means for mapping said first plurality of channels to a plurality of DSO inputs is an analog multiplexer acting in response to a set of user parameters.

15. The apparatus of claim 10 wherein the means for receiving the completion of acquisition signal further comprises a run control module receiving appropriate notification messages from a DSO.

16. The apparatus of claim 10 wherein the means for automatically mapping a second plurality of channels for eye diagram signal acquisition to the plurality of DSO inputs is the multiplexer acting in response to the completion of acquisition signal.

17. The apparatus of claim 10 wherein said display is an aggregate graphing of analysis results for all analyzed channels.
